(19) United States
(12) Patent Application Publication
(10) Pub. No.: US 2006/0077640 A1
(43) Pub. Date: Apr. 13, 2006

(54) Optical module

(75) Inventors: Satoshi Yoshikawa, Yokohama-shi (JP); Shunsuke Sato, Yokohama-shi (JP); Hiroyuki Kimura, Yokohama-shi (JP); Toshio Mizue, Yokohama-shi (JP)

Correspondence Address: MCDERMOTT WILL & EMERY LLP, 600 13TH STREET, N.W., WASHINGTON, DC, 20005-3096, US

(73) Assignee: SUMITOMO ELECTRIC INDUSTRIES, LTD.

(21) Appl. No.: 10/513,996

(22) PCT Filed: May 14, 2003
(86) PCT No.: PCT/JP03/06022

§ 371 Date: Aug. 12, 2005

(30) Foreign Application Priority Data
May 14, 2002 (JP) 2002-138968
Dec. 20, 2002 (JP) 2002-370457

(51) Int. Cl. H05K 5/03

(52) U.S. Cl. 361/752; 361/759

(57) ABSTRACT

An optical module 10 comprises a substrate 11, a light-emitting module 14, a light-receiving module 19, and a housing. The substrate 11 has a front face and a rear face. The light-emitting module 14 and light-receiving module 19 are mounted to the substrate 11. The housing receives the substrate 11. The housing comprises an upper housing 12 and a lower housing 13. The upper housing 12 is disposed on the rear face side of the substrate 11 and in contact with the rear face. The lower housing 13 is disposed on the front face side of the substrate 11 and in contact with the front face. The substrate 11 is held between the upper housing 12 and lower housing 13.

### TECHNICAL FIELD

The present invention relates to an optical module.

### BACKGROUND ART

Optical modules are used as optical transmitters or optical receivers in optical communication systems. A transmitting/receiving module functioning as both transmitter and receiver has also been known (see, for example, U.S. Patent Application Laid-Open No. 2001/0038498). FIG. 29 is a schematic sectional view showing the structure of a conventional optical module 300. This optical module 300 comprises a substrate 301, an upper housing 302, and a lower housing 303. At least one of a light-emitting module and a light-receiving module is mounted on the front face of the substrate 301. The substrate 301 is screwed onto only one of the upper housing 302 and lower housing 303. In FIG. 29, the substrate 301 is screwed onto the upper housing 302. The rear face of the substrate 301 is in contact with the inner face of the upper housing 302. The upper housing 302 and lower housing 303 are screwed together such that the upper faces of their side walls abut against each other. In FIG. 29, the contact part between the substrate 301 and the upper housing 302 is referred to with numeral 305, whereas the contact part between the substrate 301 and the lower housing 303 is referred to with numeral 310.

### DISCLOSURE OF THE INVENTION

The conventional optical module uses a relatively large number of screws for its assemblage. Through holes for the screws must be formed in the substrate, which proportionally reduce the mounting area in the substrate. Consequently, high-density mounting is difficult.

Therefore, it is an object of the present invention to increase the mounting area of a substrate within an optical module.

The optical module in accordance with the present invention comprises a substrate, at least one of a light-emitting module and a light-receiving module, and a housing. The substrate has a front face and a rear face. At least one of the light-emitting module and light-receiving module is mounted to the substrate. The housing receives the substrate. The housing comprises an upper housing and a lower housing. The upper housing is disposed on the rear face side of the substrate and in contact with the rear face. The lower housing is disposed on the front face side of the substrate and in contact with the front face. The substrate is held between the upper and lower housings.

Since the substrate is held between the upper and lower housings, the number of screws required for securing the substrate can be suppressed. Therefore, only a small number of through holes for screws are necessary in the substrate. As a consequence, a greater mounting area can be reserved in the substrate. Since the number of screws required is small, the optical module in accordance with the present invention has a high assembling workability. Since the substrate is fixed by the upper and lower housings, no screwing is necessary at locations far from lead pins of the light-emitting module or light-receiving module on the substrate. This can prevent thermal stresses from being centralized at lead pins. Since the upper and lower housings are in contact with the substrate, it will be sufficient if only the height of the lower housing from the substrate contact surface of the lower housing is taken into consideration when the lower housing is provided with an escape for a component mounted on the front face of the substrate. This makes it easier to design a tolerance.

Each of the upper and lower housings may include a bottom wall part extending along the substrate, and a side wall part provided at a peripheral portion of the bottom wall part. A peripheral part of the substrate may be held between the side wall part of the upper housing and the side wall part of the lower housing. In this case, even when a component is mounted on the substrate, the substrate can be set in the housing without interfering with the component.

At least one of upper faces of the side wall parts of the upper and lower housings may be provided with a stepped part. The substrate may be disposed within the stepped part. The substrate can be positioned only if the substrate is fitted into the stepped part, whereby the assemblage is easy.

A plurality of components may be mounted on the front face of the substrate. A partition wall may be provided on the bottom wall part of the lower housing so as to form a plurality of rooms. A plurality of components may be separately set in the plurality of rooms. Since the components are separated by the rooms, electromagnetic waves emitted from the components can be restrained from affecting the other components.

An electrical connector may be mounted on the front face of the substrate. A boss may be provided on the bottom wall part of the upper housing. The boss may abut against the rear face of the substrate at a position where the electrical connector is mounted. The boss supports the rear face of the substrate at a position where the electrical connector is mounted, and thus prevents excessive stresses from being applied to an electronic component mounted to the rear face of the substrate at a position where the electrical connector is mounted when plugging/unplugging the electrical connector.

The upper housing and lower housing may not be directly in contact with each other. A gasket may be provided in a gap between the upper and lower housings. The gasket prevents noises from leaking.

The substrate may be held between the upper and lower housings by way of an elastic member. When the substrate is held by way of the elastic member, unlike the case where it is completely secured rigidly, the substrate is allowed to move slightly because of thermal deformations, so that stresses on connecting parts between the substrate and individual members due to differences in linear expansion coefficient from that of the housing can be alleviated.

An electrical connector may be mounted on the front face of the substrate. The elastic member may be disposed between the lower housing and the front face of the substrate. In this case, the force applied to the substrate when unplugging the electrical connector is received by the lower housing by way of the elastic member.

The elastic member may be constituted by a silicone-based conductive material. The elastic member may be constituted by a metal material as well. The elastic member may be constituted by a leaf spring piece provided in at least one of the upper and lower housings.

An elastic member may be provided between the upper face of the partition wall and the front face of the substrate. This allows the housing to hold the substrate more reliably. Here, the substrate is supported by the partition wall by way of the elastic member and thus is allowed to move slightly because of thermal deformations unlike the case completely secured rigidly, so that stresses on connecting parts between the substrate and individual members due to differences in linear expansion coefficient from that of the housing can be alleviated.

The upper and lower housings may be connected to each other by screwing. The screwing reliably connects the upper and lower housings to each other while holding the substrate therebetween.

The upper and lower housings may be held by a clip so as to be connected to each other. The holding with the clip reliably connects the upper and lower housings to each other while holding the substrate therebetween. In this case, it is not necessary for the housing to be processed for screwing, and the assembling man hour is smaller than that in the case with screwing, whereby the assembling workability is higher. Also, it is not necessary for the substrate to be provided with an escape for screwing, whereby the mounting area of the substrate can be made greater.

A part of the upper and lower housings held by the clip may be provided with a depression fitting over the clip. When fitted into the depression, the clip does not project from the exterior of the housing. This enhances the stability of the optical module when mounted on a surface to be mounted.

The present invention will become more fully understood from the detailed description given hereinbelow and the accompanying drawings. They are given by way of illustration only, and thus should not be considered limitative of the present invention.

### BRIEF DESCRIPTION OF THE DRAWINGS

FIG. 1 is a schematic sectional view showing the structure of the optical module in accordance with an embodiment;

FIG. 2 is a schematic plan view of a substrate;

FIG. 3 is an exploded perspective view of the optical module in accordance with a first embodiment as looked down from the upper housing side;

FIG. 4 is an exploded perspective view of the optical module in accordance with the first embodiment as looked up from the lower housing side;

FIG. 5 is a sectional view of the optical module in accordance with the first embodiment;

FIGS. 6 to 13 are perspective views showing a procedure of assembling the optical module in accordance with the first embodiment;

FIG. 14 is a perspective view showing the configuration of the optical module in accordance with a second embodiment;

FIG. 15 is an exploded perspective view of the optical module in accordance with the second embodiment as looked up from the lower housing side;

FIG. 16 is an exploded perspective view of the optical module in accordance with the second embodiment as looked down from the upper housing side;

FIG. 17 is a view showing the positional relationship between a lower housing and an elastic member;

FIGS. 18 and 19 are perspective views showing a procedure of assembling the optical module in accordance with the second embodiment;

FIG. 20 is a sectional view of the optical module in accordance with the second embodiment taken along the line XX-XX of FIG. 14;

FIG. 21 is a perspective view showing the configuration of the optical module in accordance with a third embodiment;

FIG. 22 is a perspective view showing a state where clips are removed from the optical module in accordance with the third embodiment;

FIG. 23 is a sectional view of the optical module in accordance with the third embodiment taken along the line XXIII-XXIII of FIG. 22;

FIG. 24 is a partial sectional view of the optical module in a state mounted with a clip;

FIG. 25 is an exploded perspective view of the optical module in accordance with the third embodiment as looked up from the lower housing side;

FIG. 26 is an exploded perspective view of the optical module in accordance with the third embodiment as looked down from the upper housing side;

FIGS. 27A and 27B are sectional views showing an operation of assembling the optical module in accordance with the first embodiment equipped with a gasket;

FIG. 28 is a view for explaining a modified example of an elastic member provided in the optical module in accordance with the second embodiment; and

FIG. 29 is a schematic sectional view showing the structure of an optical module in accordance with the prior art.

### BEST MODES FOR CARRYING OUT THE INVENTION

In the following, embodiments of the present invention will be explained in detail with reference to the accompanying drawings. In the explanation of the drawings, constituents identical to each other will be referred to with numerals identical to each other without repeating their overlapping descriptions. For convenience of illustration, ratios of dimensions in the drawings do not always match those explained.

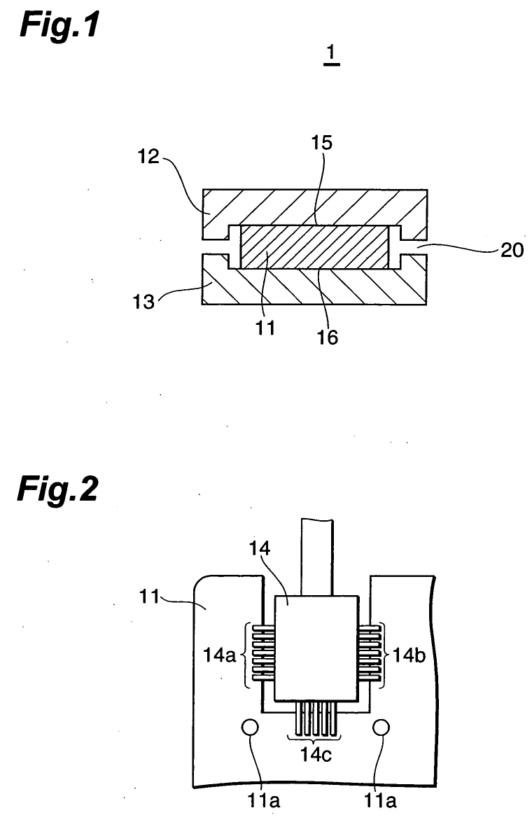

First, the outline of embodiments which will be set forth later will be explained with reference to FIG. 1. FIG. 1 is a schematic sectional view showing the structure of the optical module 1 in accordance with an embodiment. As can be seen when FIG. 29 showing the prior art is compared with FIG. 1, the optical module 1 configures a substrate supporting method different from the conventional one. In this embodiment, the substrate 11 is held between the upper housing 12 and the lower housing 13. In FIG. 1, the contact part between the substrate 11 and the upper housing 12 is referred to with numeral 15, whereas the contact part between the substrate 11 and the lower housing 13 is referred to with numeral 16.

This embodiment differs from the prior art in that the substrate is in contact with both of the upper housing 12 and lower housing 13. Since the substrate 11 is held between the upper housing 12 and lower housing 13, the number of screws required for assembling the optical module 1 can be reduced.

In the conventional optical module 300, by contrast, the substrate 301 is held by only one of the upper housing 302 and lower housing 303. Therefore, a number of screws are necessary for securing the substrate 301 onto the upper housing 302. This generates some problems. For example, a number of through holes for the screws must be formed in the substrate. As a result, the mounting area of the substrate becomes smaller. This makes high-density mounting difficult. Also, the assembling efficiency is not favorable, since a large number of screws is necessary for assemblage.

However, this embodiment is not totally free of screws. The substrate 11 is secured to the upper housing 12 by two screws. These screws are used for temporary fastening at the time of assembling. FIG. 2 is a schematic plan view of the substrate 11. An LD (laser diode) module 14 is mounted on the front face of the substrate 11. The LD module 14 is of butterfly type. Lead pins 14a, 14b, and 14c of the LD module 14 are soldered to the substrate 11. Through holes 11a for passing the screws are formed near the LD module 14. They aim at preventing thermal stresses from being centralized at the lead pins 14a to 14c. This will be explained later.

### First Embodiment

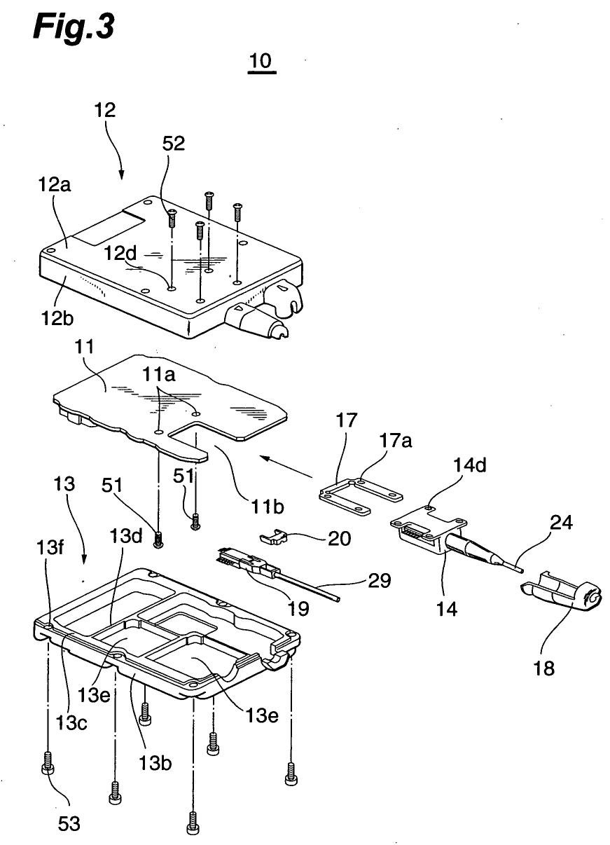

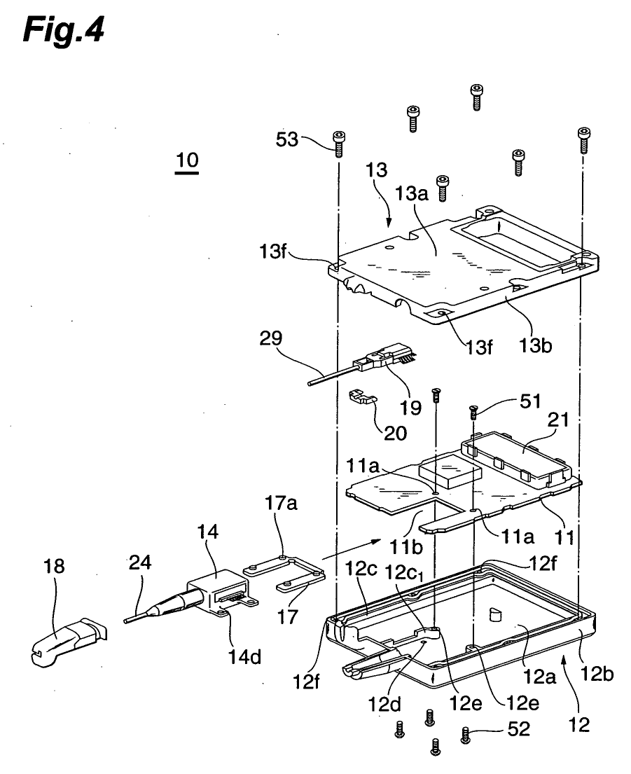

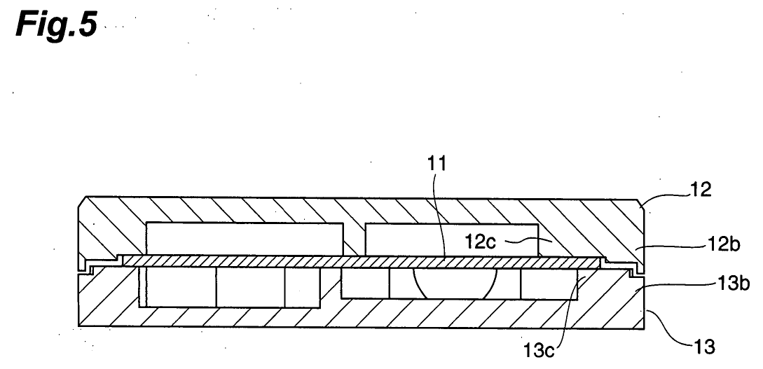

In the following, the structure of the optical module 10 in accordance with the first embodiment will be explained in detail with reference to FIGS. 3 to 5. FIG. 3 is an exploded perspective view of the optical module 10 as looked down from the upper housing 12 side. FIG. 4 is an exploded perspective view of the optical module 10 as looked up from the lower housing 13 side. FIG. 5 is a sectional view of the optical module 10.

The optical module 10 is a transmitter/receiver for optical communications. The optical module 10 comprises a substrate 11, an upper housing 12, and a lower housing 13. An LD module 14, a Pin AMP 19, and other components (a control circuit, an electrical connector 21, etc.) are mounted on the front face of the substrate 11. The LD module 14 is a light-emitting module, whereas the Pin AMP 19 is a light-receiving module. The LD module 14 incorporates a laser diode therein. The Pin AMP 19 incorporates a photodiode therein. The LD module 14 includes an optical fiber 24 for outputting light. The Pin AMP 19 includes an optical fiber 29 for inputting light. A sheet metal nut 17 and an EO cap 18 are attached to the LD module 14. An OE cap 20 is attached to the Pin AMP 19.

The substrate 11 is formed with two through holes 11a. At the time of assembling the optical module 10, screws 51 are inserted through the through holes 11a for temporarily fastening the substrate 11. The substrate 11 is also provided with a cutout 11b for inserting the LD module 14. The holes 11a are disposed near the cutout 11b.

As shown in FIG. 4, the upper housing 12 has a substantially square bottom wall part 12a, and a side wall part 12b extending substantially perpendicularly from fringes of the bottom wall part 12a. For supporting the substrate 11, the upper face of the side wall part 12b is formed with a ring-like stepped part. When assembling the optical module 10, the substrate 11 is fitted into the stepped part and thus is positioned. The stepped part makes the upper face of the inner portion 12c of the side wall part 12b lower than the upper face of the outer part. As shown in FIG. 5, the upper face of the inner portion 12c comes into contact with the rear face of the substrate 11. This inner portion will be referred to as upper support part. The upper support part 12c projects inward from the inner face of the side wall part 12b. The upper support part 12c includes an elongated extension 12c₁. The extension 12c₁ extends from the center of the front portion of the side wall part 12b toward the center of the bottom wall part 12a.

The bottom wall part 12a is formed with four through holes 12d. Screws 52 are inserted through the holes 12d, respectively. The screws 52 are threaded into screw holes 14e of the LD module 14 and screw holes 17a of the sheet metal nut 17. This secures the LD module 14 to the upper housing 12. The upper support part 12c is formed with two screw holes 12e. One of the screw holes 12e is formed in the extension 12c. These screw holes 12e are positioned directly under the through holes 11a of the substrate 11 when the substrate 11 is mounted on the upper support part 12c. The screws 51 are threaded into the screw holes 12e by way of the holes 11a. This temporarily secures the substrate 11 to the upper housing 12. The side wall part 12b of the upper housing 12 is further formed with six screw holes 12f. These screw holes 12f are disposed on the outside of the upper support part 12c in the side wall part 12b. Therefore, the screw holes 12f are disposed on the outside of the screw holes 12e used for temporarily securing the substrate. The screw holes 12f are disposed at positions corresponding to the through holes 13f in the lower housing 13.

As shown in FIG. 3, the lower housing 13 comprises a substantially quadrangular bottom wall part 13a, and a side wall part 13b extending substantially perpendicularly from the bottom wall part 13a. The bottom wall part 13a has a size substantially identical to that of the bottom wall part 12a of the upper housing 12. The upper face of an inner portion 13c of the side wall part 13b is higher than the upper face of the outer portion. As shown in FIG. 5, the upper face of the inner portion 13c comes into contact with the front face of the substrate 11. This inner portion will be referred to as lower support part.

Disposed on the bottom wall part 13a is a partition wall 13d extending substantially perpendicularly from the bottom wall part 13a. The partition wall 13d forms a plurality of rooms 13e on the bottom wall part 13a. The components mounted on the substrate 11 are separately set in the rooms 13e. Since the components are separated from each other by the partition wall 13d, electromagnetic waves emitted from components can be restrained from affecting the other components.

The side wall part 13b is formed with six through holes 13f. The holes 13f are disposed on the outside of the lower support part 13c in the side wall part 13b. When assembling the optical module 10, screws 53 are inserted through the holes 13f in order to secure the lower housing 13 to the upper housing 12. The screws 53 are threaded into the screw holes 12f of the upper housing 12 by way of the holes 13f. This secures the lower housing 13 to the upper housing 12. FIG. 5 omits the screws 53, screw holes 12f, and through holes 13f.

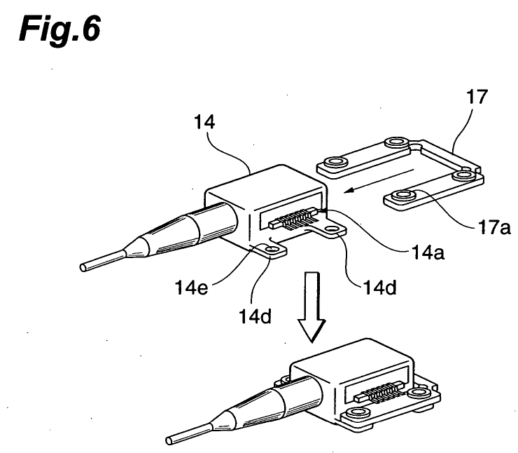

In the following, a procedure of assembling the optical module 10 will be explained with reference to FIGS. 6 to 13. FIGS. 6 to 13 are perspective views showing the procedure of assembling the optical module 10.

First, as shown in FIG. 6, the sheet metal nut 17 is assembled to the LD module 14. Both side parts of the LD module 14 are provided with four flanges 14d. The screw holes 14e are formed in the flanges 14d. The flanges 14d are positioned lower than the lead pins 14a, 14b on the left and right sides of the LD module 14. The sheet metal nut 17 is inserted between the lead pins 14a, 14b and the flanges 14d from behind the LD module 14. The sheet metal nut 17 is positioned such that the screw holes 14e of the LD module are overlaid on the screw holes 17a of the sheet metal nut 17. The sheet metal nut 17 is supported by the flanges 14d. The lead pins 14a to 14c are disposed above the sheet metal nut 17.

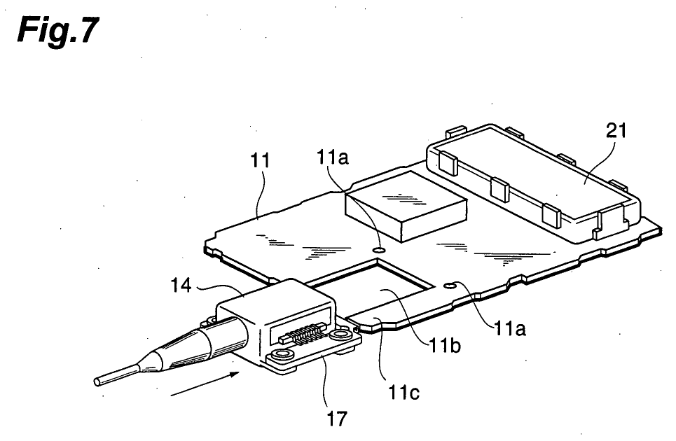

The LD module 14 assembled with the sheet metal nut 17 is assembled to the substrate 11 as shown in FIG. 7. The LD module 14 and the sheet metal nut 17 are inserted into the cutout 11b. A periphery 11c of the cutout 11b in the substrate 11 is inserted between the lead pins 14a to 14c and the metal sheet nut 17.

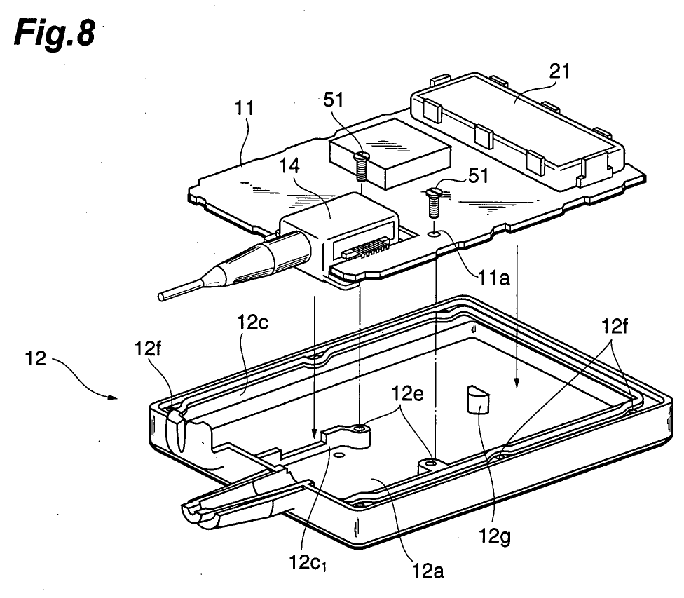

Thereafter, the substrate 11 assembled with the LD module 14 is softly mounted on the upper housing 12 as shown in FIG. 8. Here, the front face (mounting surface) of the substrate 11 is faced up. Fringes of the rear face of the substrate 11 abut against the upper face of the upper support part 12c. As a result, the substrate 11 is supported by the upper support part 12c. An abutment boss 12g is disposed on the bottom wall part 12a. The abutment boss 12g is arranged such as to abut against the rear face of the substrate 11 at a position where the electrical connector 21 is mounted. Advantages of the boss 12g will be explained later. The substrate 11 is temporarily secured to the upper housing 12 by two screws 51.

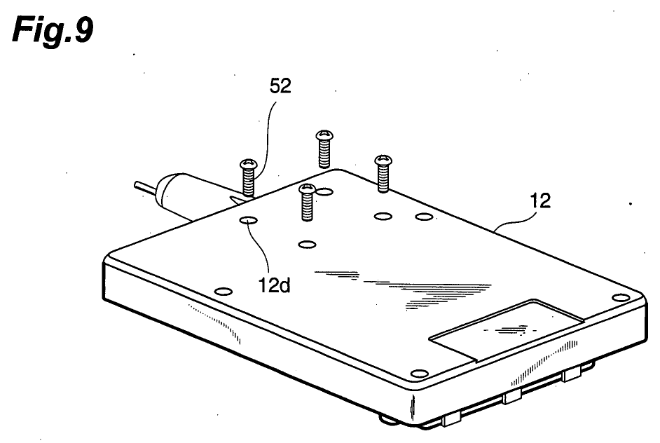

Next, the upper housing 12 is reversed, and the screws 52 are inserted into the through holes 12d of the upper housing 12 as shown in FIG. 9. The upper housing 12 is reversed while in a state where the lead pins 14a to 14c are positioned to pads on the substrate 11. The lead pins 14a to 14c will later be soldered to the pads. The screws 52 are inserted through the through holes 12d of the upper housing 12, so as to be threaded into the screw holes 17e of the sheet metal nut and the screw holes 14e of the LD module. This secures the LD module 14 and sheet metal nut 17 to the upper housing 12.

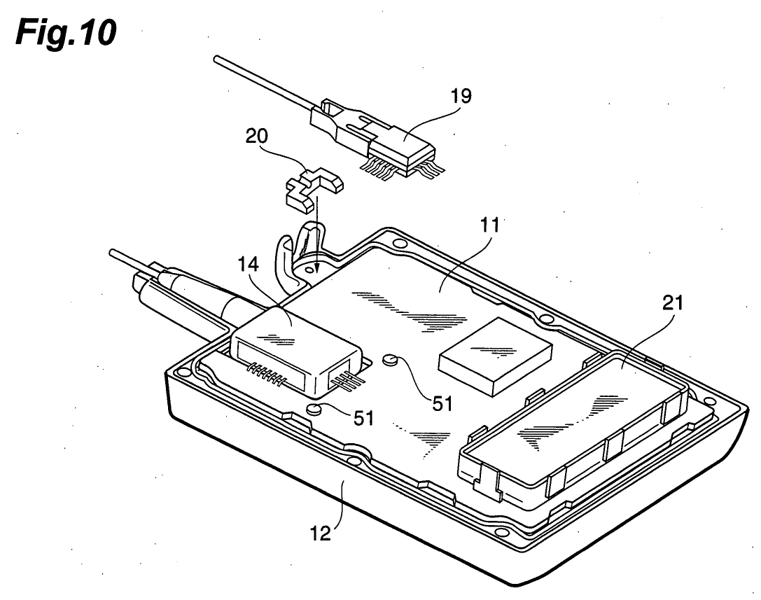

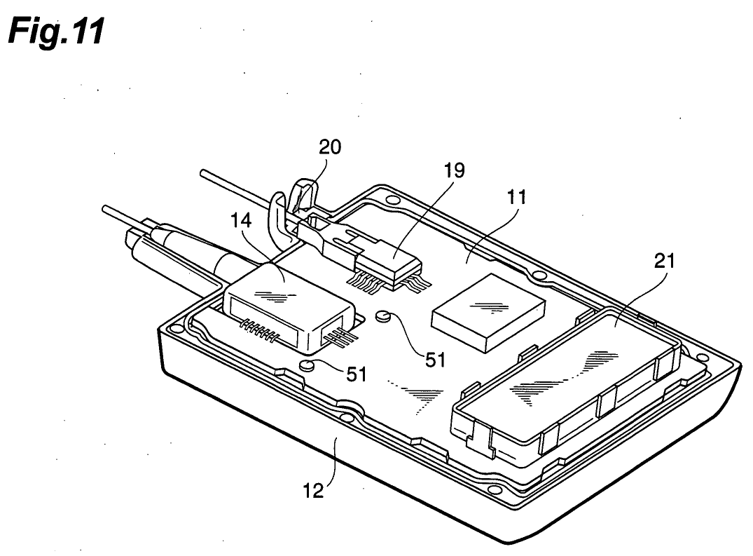

Subsequently, as shown in FIG. 10, the LD module 14 and Pin AMP 19 are soldered onto the substrate 11. The lead pins 14a to 14c of the LD module 14 are soldered to the pads on the substrate 11. When soldering the Pin AMP 19, the OE cap 20 is disposed on the upper housing 12, and then the Pin AMP 19 is placed on the substrate 11. Thereafter, the lead pins of the Pin AMP 19 are soldered to the pads on the substrate 11. Thus, the LD module 14 and Pin AMP 19 are mounted on the substrate 11 (FIG. 11).

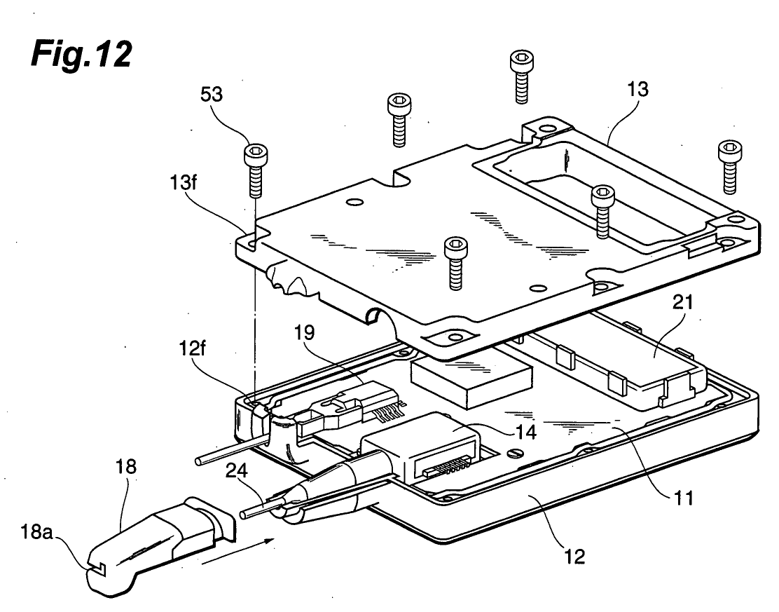

Thereafter, as shown in FIG. 12, the EO cap 18 and the lower housing 13 are attached to the upper housing 12. First, the optical fiber 24 of the LD module 14 is passed through the cutout 18a at the leading end of the EO cap 18. Here, the optical fiber 24 is slowly inserted into the cutout 18a so as not to be damaged. Subsequently, the lower housing 13 is placed on the front face of the substrate 11 so as to cover the latter, and is screwed to the upper housing 12. The screws 53 are inserted through the through holes 13f of the lower housing 13 and are threaded into the screw holes 12f of the upper housing 12. Peripheral parts of the front face of the substrate 1 abut against the upper face of the lower support part 13c. The EO cap 18 is held by the upper housing 12 and lower housing 13.

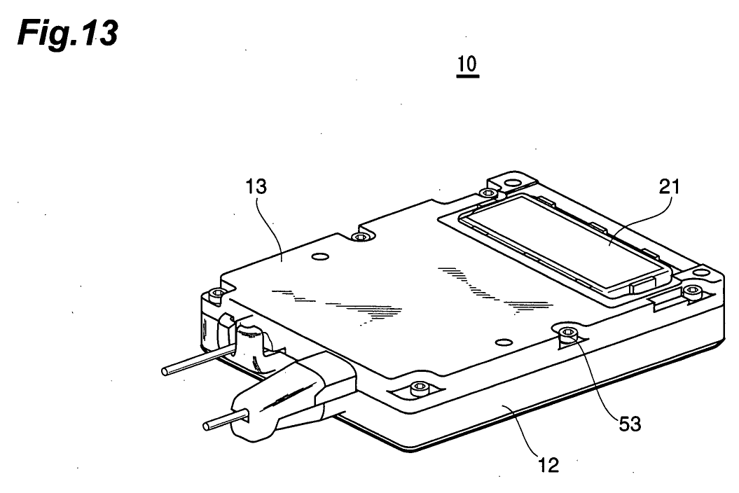

Thus, the upper housing 12 and lower housing 13 are assembled together, so as to complete the optical module 10 (FIG. 13). As shown in FIG. 5, peripheral parts of the substrate 11 are held between the upper support part 12c of the upper housing 12 and the lower support part 13c of the lower housing 13. The side wall part 13b of the lower housing and the side wall part 12b of the upper housing are separated from each other. Outer edges of the side wall part 13 of the lower housing slightly project upward. Outer edges of the side wall part 13b of the lower housing 13 are slightly depressed downward. These outer edges come into mesh with each other when the upper housing 12 and lower housing 13 are assembled together. However, they are not in contact with each other. Such a structure can suppress the leakage of noise from within the optical module 10.

Advantages of this embodiment will now be explained. There are five major advantages in this embodiment.

First, the optical module 10 has high mounting and wiring densities. This is because the substrate 11 is held between the upper housing 12 and lower housing 13. The holding makes the screws for securing the substrate 11 to any of the housings wholly or partly unnecessary. Therefore, the optical module 10 can be assembled with a relatively small number of screws. Since only a small number of screws are necessary, the number of through holes for inserting the screws can be reduced in the substrate 11. Therefore, a greater mounting area can be reserved on the substrate 11. As the number of through holes in the substrate 11 decreases, the degree of freedom in the inner layer wiring in the substrate 11 increases. Hence, the mounting and wiring densities can be enhanced.

Second, the optical module 10 is tolerant of temperature changes. This is because the substrate 11 is held between the upper housing 12 and lower housing 13. When temperature changes, a thermal stress is applied to the substrate because of the difference in linear expansion coefficient between the substrate material and the housing material. The thermal stress distribution depends on the position of the connecting part between the substrate and housing. In the conventional optical module, the substrate is secured to the housing by screws alone (FIG. 29). The substrate and housing are connected to each other only at the screwing positions. For securing the substrate with screws alone, not only positions near the lead pins of the LD module but also positions far from the lead pins must be screwed. When the substrate and housing are connected together at positions far from the lead pins, however, a large thermal stress is applied to the lead pins. This causes the lead pins to break. In this embodiment, by contrast, the substrate 11 is held between the upper housing 12 and lower housing 13, so that there is no need to screw positions far from the lead pins of the LD module 14. This can suppress the thermal stress applied to the lead pins.

Third, the optical module 10 is excellent in assembling workability. This is because the number of screws necessary for assemblage is smaller.

Fourth, the optical module 10 is easy to design its tolerance. This is because the substrate 11 is in contact with both of the upper housing 12 and lower housing 13. Suppose a case where the lower housing is provided with an escape for a mounting component in order to prevent the mounting component on the front face of the substrate and the lower housing from interfering with each other. In the conventional optical module, the upper and lower housings come into contact with each other, whereas the lower housing does not come into contact with the substrate (FIG. 29). Therefore, tolerances of processing for both housings and the tolerance of thickness for the substrate must be taken into consideration when designing the escape for the mounting component. Hence, the tolerances are troublesome to design. In this embodiment, by contrast, both of the upper and lower housings are in contact with the substrate 11. The lower housing 13 is placed on the front face of the substrate 11 and covers the mounting component. Therefore, only the processing tolerance of the lower housing 13 is the tolerance to be taken into consideration at the time of designing. Hence, the tolerance is easy to design. Also, stricter designing is possible. As a consequence, a heat dissipation path can be designed more strictly.

Fifth, an excessive stress can be prevented from being applied to electronic components mounted on the rear face of the substrate 11 at a position where the electrical connector 21 is mounted. This is because the upper housing 12 is provided with the boss 12g abutting against the rear face at a position where the connector is mounted. The electrical connector 21 is an electrical interface for the optical module 10. For high-density mounting, an electronic component is also mounted on the rear face at a position where the electrical connector 21 is mounted in this embodiment. The electrical connector 21 on the substrate is plugged/unplugged into/from its corresponding external connector (not depicted). The plugging/unplugging exerts a stress on the rear face at a position where the electrical connector 21 is mounted. The boss 12g alleviates the stress.

### Second Embodiment

A second embodiment of the present invention will now be explained. Constituents identical to those explained in the above-mentioned first embodiment will be referred to with numerals identical thereto without repeating their overlapping descriptions.

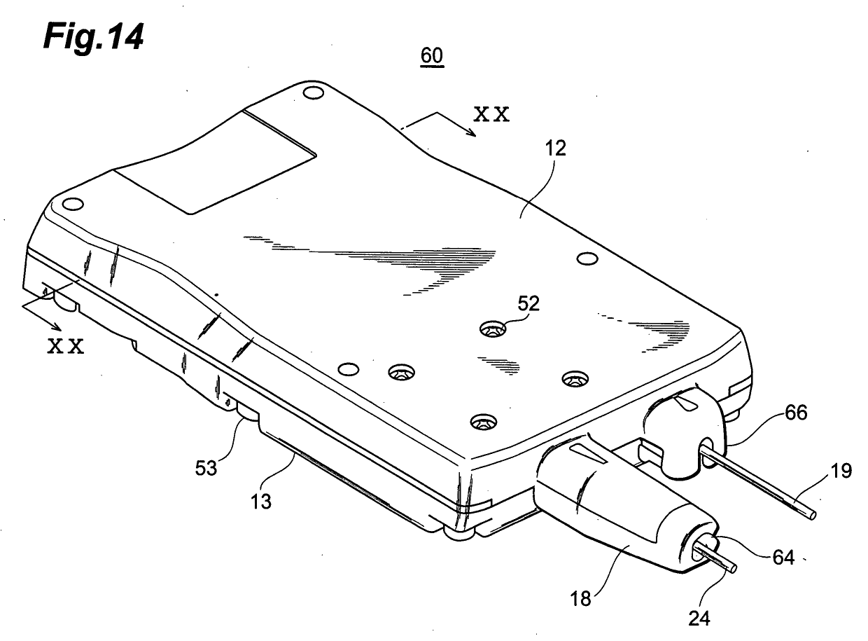

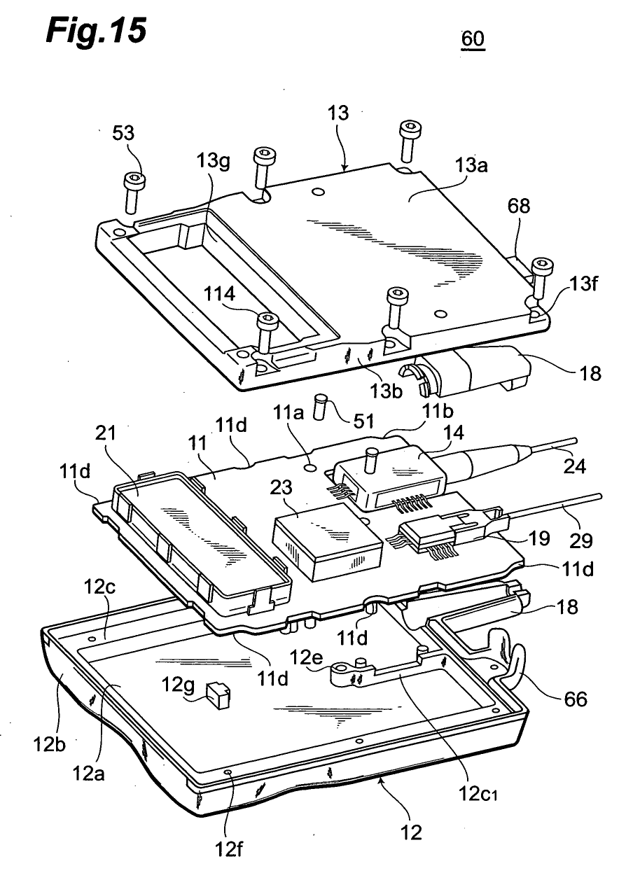

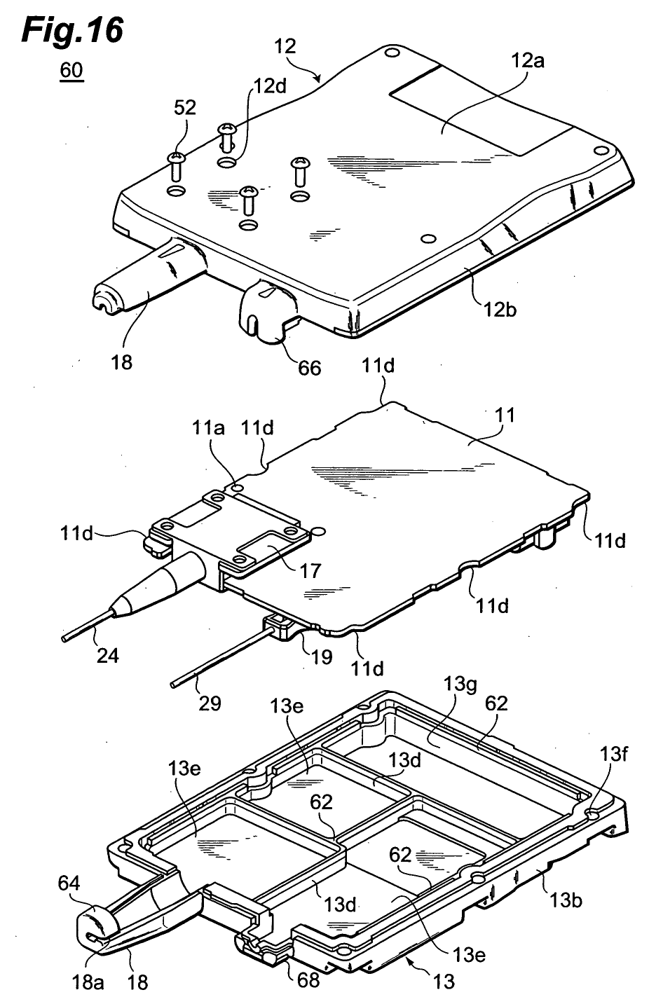

FIG. 14 is a perspective view showing the configuration of the optical module in accordance with the second embodiment. FIGS. 15 and 16 are exploded perspective views showing the configuration of the optical module in accordance with the second embodiment.

As shown in FIGS. 14 to 16, this optical module 60 comprises an LD module 14, a Pin AMP 19, a semiconductor circuit device 23, an electrical connector 21, a substrate 11, a housing (an upper housing 12 and a lower housing 13), etc.

As shown in FIG. 15, the LD module 14 is a module of butterfly package type as with the LD module in the optical module 10 in accordance with the above-mentioned first embodiment.

As shown in FIG. 15, the Pin AMP 19 is a surface-mounted module as with the Pin AMP in the optical module 10 in accordance with the above-mentioned first embodiment.

The semiconductor circuit device 23 is an integrated transmitting/receiving semiconductor circuit device 23 (e.g., LSI) including a BGA (Ball grid array), and is electrically connected to the LD module 14 and Pin AMP 19. The semiconductor circuit device 23 generates and outputs a signal for controlling the driving of the LD module 14, and shapes, amplifies, and outputs the signal received by the Pin AMP 19.

The electrical connector 21 is a male connector (or female connector) constituted by the BGA and a plurality of lead pins (or a receptacle adapted to mate with the lead pins) as with the electrical connector in the optical module 10 in accordance with the first embodiment. For inputting/outputting a plurality of low-rate signals into/from the substrate within the housing, the BGA enables terminals of the electrical connector 21 to achieve a higher density. The electrical connector 21 is connected to a female connector (or male connector) on an undepicted mounting substrate on which the optical module 60 is mounted, so that they are electrically connected to each other.

The substrate 11 has a substantially rectangular outer form with front and rear faces printed with wiring. This substrate 11 is the same as that in the optical module 10 in accordance with the above-mentioned first embodiment.

The housing is used for receiving and holding the substrate 11, and is formed from a metal such as aluminum or copper. In view of thermal conductivity, cost, etc., aluminum is preferred. The housing comprises the upper housing 12 and lower housing 13. As shown in FIG. 15, the upper housing 12 includes a bottom wall part 12a extending along the substrate 11, and a side wall part 12b provided at fringes of the bottom wall part 12a.

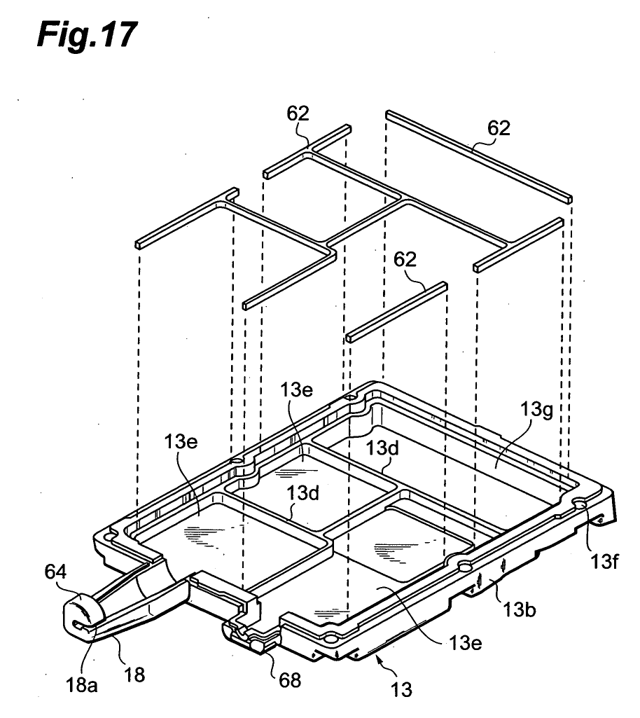

As shown in FIG. 16, the lower housing 13 includes a bottom wall part 13a extending along the substrate 11, and a side wall part 13b provided at fringes of the bottom wall part 13a. The portion of the bottom wall part 13a corresponding to the electrical connector 21 is pierced so as to form an opening 13g. As shown in FIGS. 16 and 17, the inner upper end portion of the side wall part 13b is cut out so as to yield a stepped part. The substrate 11 fits into the stepped part and thus can be positioned. An elastic member 62 is disposed on the stepped part.

When holding the substrate 11 between the upper housing 12 and lower housing 13, the elastic member 62 functions to substantially prevent the substrate 11 from moving and reliably hold the same while allowing the substrate 11 to slightly move because of thermal deformations. In view of EMI (Electro-Magnetic Interference) or enforcement of grounding, the elastic member 62 is preferably formed from a material having conductivity. Therefore, it will be preferred if the elastic member 62 is formed from a silicone-based conductive material or a metal material. Preferred as the metal material is not only copper alloys for springs such as phosphor bronze, beryllium copper, and titanium copper, but also steels for springs such as stainless. It will be preferred if the elastic member 62 is formed from a silicone-based conductive material, since it can adhere to the side wall part 13b of the lower housing 13 because of its own adhesive force and thus is easier to handle.

A partition wall 13d projects from the bottom wall part 13a of the lower housing 13. The partition wall 13d is formed from a metal such as aluminum. This shields the LD module 14 from the Pin AMP 19 and semiconductor circuit device 23. In view of the thermal conductivity, it will be preferred if the partition wall 13d is integrally formed from the same metal as with the housing 13. Then, as shown in FIGS. 16 and 17, the elastic member 62 is disposed on the partition wall 13d as on the stepped part of the side wall part 13b. This enables the substrate 11 to be held more reliably.

As shown in FIGS. 14 to 16, the EO cap 18 is a cylindrical member disposed so as to cover the LD module 14, and is formed from a metal such as aluminum or copper. In view of thermal conductivity, etc., aluminum is preferred. The EO cap 18 is divided along its axis, and thus comprises an upper cap piece and a lower cap piece.

Here, the upper cap piece is integrally formed with the side wall part 12b of the upper housing 12 on the foreside thereof. By contrast, the lower cap piece is provided separately from the housings. The lower cap piece includes a base end part held between the upper housing 12 and lower housing 13. Thus, the lower cap piece can be held between the upper housing 12 and lower housing 13 by way of the base end part, so as to be connected to the housing. Therefore, operations of applying an adhesive or the like, welding, screwing, etc. become unnecessary, whereby production efficiency improves.

The lower cap piece includes a leading end part provided with a latch 64 having a spring property. The latch 64 is cantilevered at the leading end part of the lower cap piece, whereas the leading end of the latch 64 is formed with a cutout 18a. The cutout 18a is provided in order to pass therethrough the optical fiber 24 of the LD module 14. The latch 64 engages the leading end part of the upper cap piece so as to surround the same, thereby securing the upper and lower cap pieces to each other. Since the upper and lower cap pieces can be secured to each other by way of the latch 64 as such, operations of applying an adhesive or the like, welding, screwing, etc. become unnecessary, whereby production efficiency improves.

The side wall part 12b on the foreside of the upper housing 12 is integrally formed with a positioning part 66 for positioning the Pin AMP 19. The positioning part 66 is formed with a guide groove for guiding the optical fiber 29. The side wall part 13b on the foreside of the lower housing 13 is integrally formed with a pressing part 68 for pressing the Pin AMP 19 positioned by the positioning part 66.

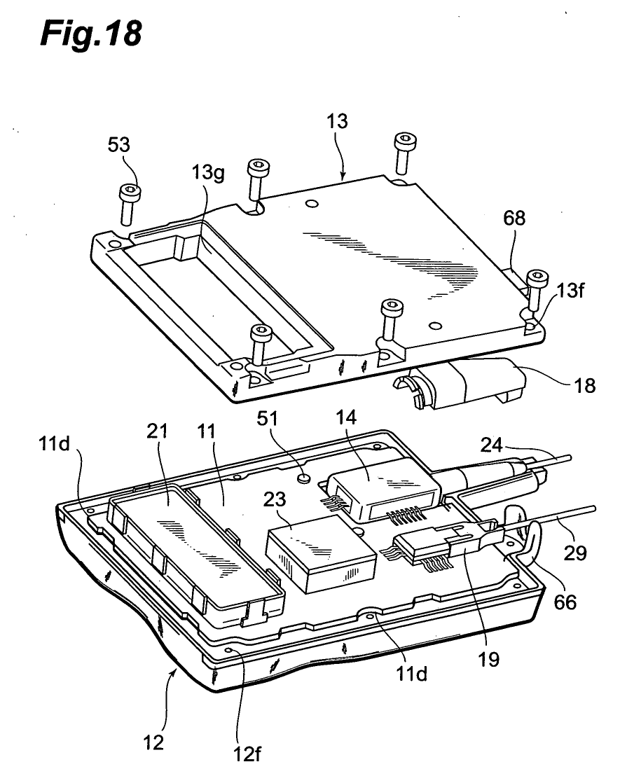

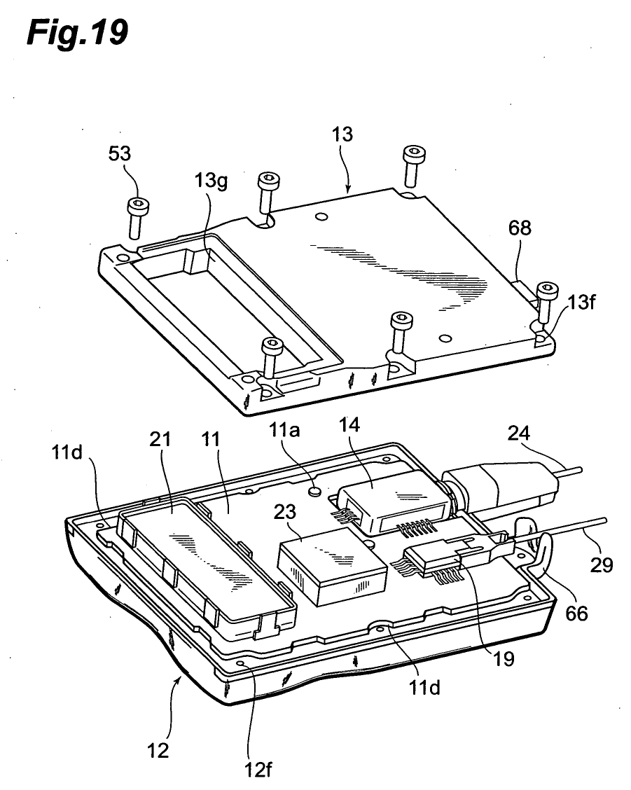

Thus configured LD module 14 and Pin AMP 19 are mounted on the substrate 11 by soldering, etc. Also, the semiconductor circuit device 23 is mounted on the substrate 11. Further, the electrical connector 21 is mounted on the substrate 11. As shown in FIG. 18, the substrate 11 mounted with these members is temporarily fastened with a screw 51 so as not to drop out of the upper housing 12 by handling during assembling. The screw 51 does not use any spring washer as measures against creeps, so as not to obstruct its effect of alleviating stresses on connecting parts to the individual members due to differences in linear expansion, but utilizes creeps so as not to inhibit the substrate 11 from moving in planar directions. Also, the temporary securing screw 51 is disposed in the close vicinity of the LD module 14 that will be affected most greatly if the movement is inhibited. The LD module 14 is set in the EO cap 18, whereas the Pin AMP 19 is positioned by the positioning part 66. The LD module 14 is secured to the upper housing 12 by the screws 52 and sheet metal nut 17 (see FIG. 16). Here, as shown in FIGS. 15 and 16, the substrate 11 is provided with six cutouts 11d. Therefore, as shown in FIGS. 18 and 19, the upper housing 12 and lower housing 13 are fastened to each other with the screws 53 without being obstructed by the substrate 11, while the cutouts 11d function as escapes for the screws 53.

Further, as shown in FIG. 19, the lower cap piece is assembled and secured to the upper cap piece by way of the latch 64. The lower housing 13 is assembled to the upper housing 12 with six screws 53. Here, the lower cap piece is held between the upper housing 12 and lower housing 13 by way of the base end part. The pressing part 68 presses and secures the Pin AMP 19. While being fitted into and positioned by the stepped part formed in the side wall part 13b of the lower housing 13, the substrate 11 is held between the side wall part 12b of the upper housing 12 and the side wall part 13b of the lower housing 13 by way of the elastic member 62.

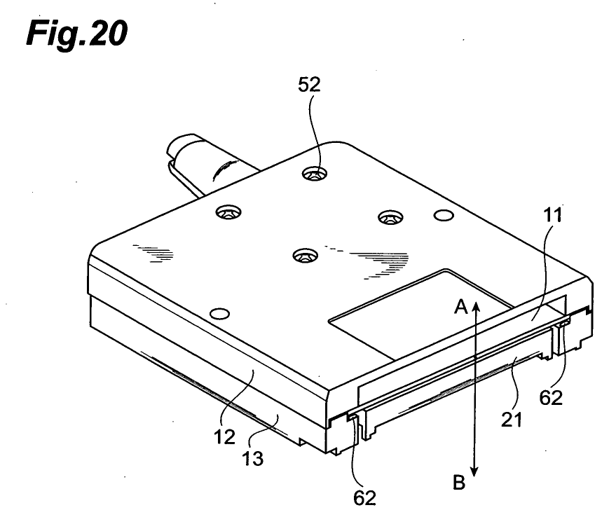

Thus, the optical module 60 in accordance with this embodiment shown in FIG. 14 is constructed. FIG. 20 is a sectional view of the optical module 60 taken along the line XX-XX of FIG. 14. It is seen from FIG. 20 that, while being fitted into and positioned by the stepped part formed in the side wall part 13b of the lower housing 13, the substrate 11 is held between the side wall part 12b of the upper housing 12 and the side wall part 13b of the lower housing 13 by way of the elastic member 62.

Advantages of this embodiment will now be explained. This embodiment has three advantages in addition to the five advantages explained in the above-mentioned first embodiment.

First, the substrate 11 is held by way of the elastic member 62 and thus is allowed to move slightly because of thermal deformations unlike the case where it is completely secured rigidly. This can alleviate the fear of stresses being exerted on connecting parts between the substrate 11 and the individual members such as LD module 14 because of differences in linear expansion between the housings 12, 13.

Second, as shown in FIG. 20, the force in B direction acting when unplugging the electrical connector 21 from an external connector is received by the side wall part 13b of the lower housing 13 by way of the elastic member 62. This lowers the shock and distortion acting on the substrate 11 when unplugging the electrical connector 21. Under such circumstances, it will be preferred if the elasticity of the elastic member 62 is adjusted to such an extent that it is not defeated by the force in B direction acting when unplugging the electrical connector 21 from the external connector. The force in A direction acting when connecting the electrical connector 21 to the external connector is received by the side wall part 12b and boss 12g of the upper housing 12.

Third, the substrate 11 is also supported by the partition wall 13d of the lower housing 13 by way of the elastic member 62 and thus is more reliably supported while being allowed to move slightly because of thermal distortions.

### Third Embodiment

The third embodiment of the present invention will now be explained. Constituents identical to those explained in the above-mentioned first and second embodiments will be referred to with numerals identical thereto without repeating their overlapping descriptions.

In the optical modules 10, 60 of the above-mentioned first and second embodiments, the upper housing 12 and lower housing 13 are connected to each other by being fastened with the six screws 53. In the optical module 80 of the third embodiment, by contrast, the upper housing 12 and lower housing 13 are held by clips 82 instead of screwing, so as to be connected to each other. On the basis of the optical module 60 in accordance with the second embodiment, the optical module 80 of the third embodiment will now be explained.

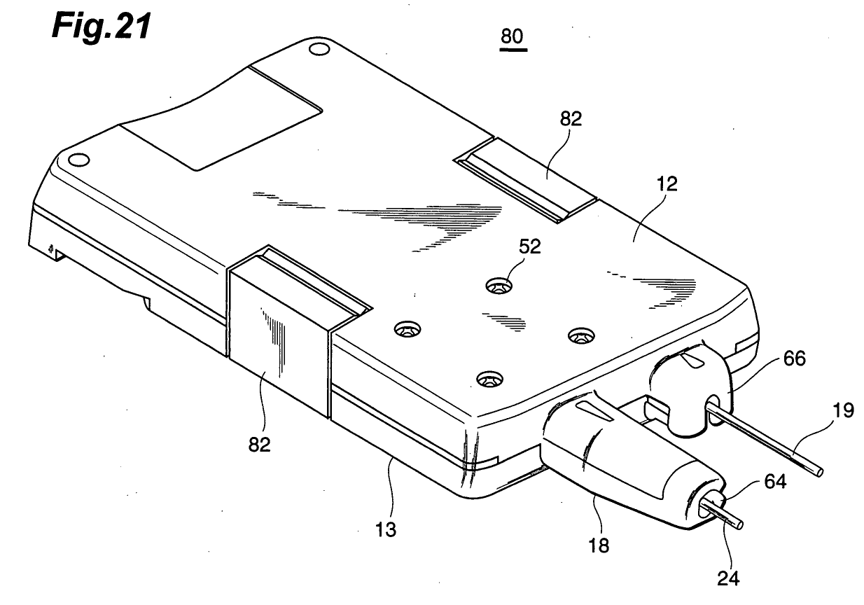

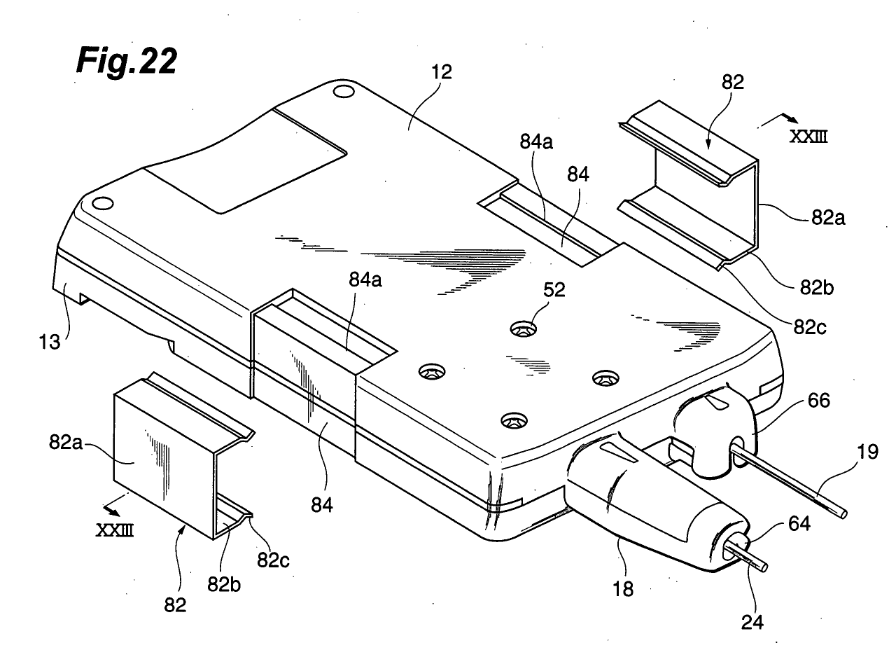

FIG. 21 is a perspective view showing the optical module 80 in accordance with the third embodiment. FIG. 22 is a perspective view showing the optical module 60 in a state free of the clips 82.

In this optical module 80, as shown in FIG. 21, the upper housing 12 and lower housing 13 are connected to each other with their both edge parts being held by a pair of clips 82. As shown in FIG. 22, each clip 82 comprises a flat base part 82a and leaf spring parts 82b formed by bending the upper and lower edge portions of the base part 82a. The vertical width of the base part 82a is substantially the same as the thickness of the optical module 80 when the upper housing 12 and lower housing 13 are overlaid on each other.

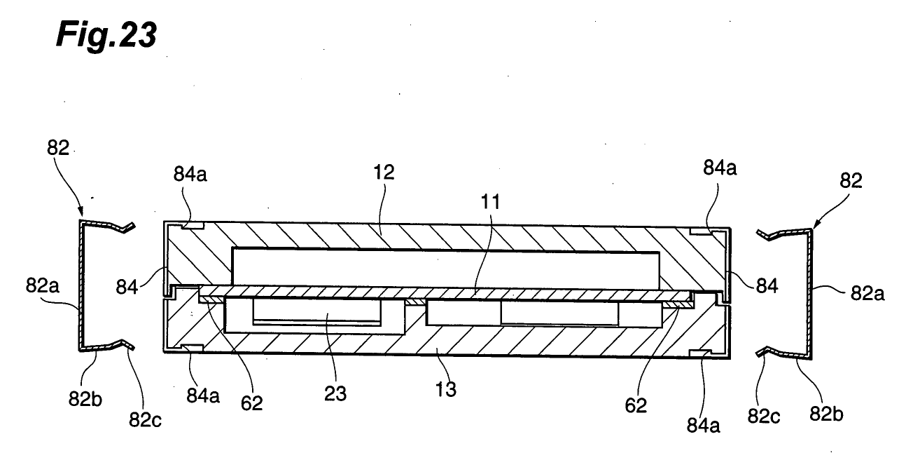

FIG. 23 is a sectional view of the optical module 80 taken along the line XXIII-XXIII of FIG. 22. As shown in FIG. 23, a pair of leaf spring parts 82b of the clip 82 is bent at acute angles from the base part 12a. This improves the feel of attachment when attaching the clip 82. Leading end portions 82c of the pair of leaf spring parts 82b are once bent inward and then outward, so as to widen the space therebetween. Hence, each leading end part 82c has a substantially V-shaped cross section. As a consequence, the clip 82 is smoothly attached by simply butting the leading end portions 82c of the pair of leaf spring parts 82b against a part to which the clip 82 is to be attached, and pushing the clip 82 therein.

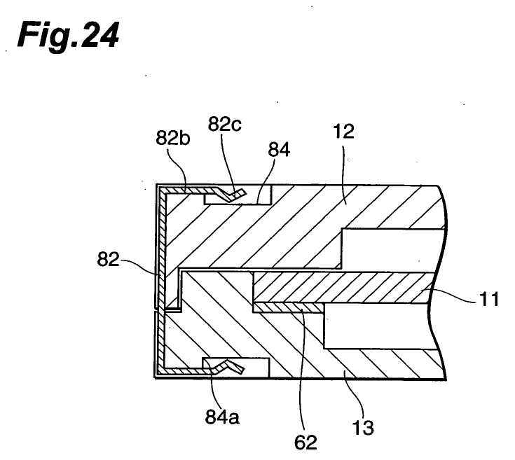

As shown in FIGS. 22 and 23, the parts of the upper housing 12 and lower housing 13 to which the clips 82 are to be attached are formed with depressions 84 into which the clips 82 fit. Therefore, as shown in FIGS. 21 and 24, the clips 82 fit into the depressions 84 without protruding from the exterior of the housings 12, 13. As a result, stability becomes higher when mounting the optical module 80 onto a mounting surface which is not depicted, and thus obtained smart look improves the design effect.

Here, the bottom faces of the depressions 84 against which the leading end parts 82c of the clip 82 abut are formed deeper than the bottom faces of the other parts. This forms a pair of stepped parts 84a within each depression 84. When the clips 82 are fitted into the depressions 84, the substantially V-shaped leading end portions 82c engage the stepped portions 84a as shown in FIG. 24. This makes the clips 82 harder to disengage.

Thus, the optical module 80 configures that the upper housing 12 and lower housing 13 are held by a pair of clips 82, whereby the structures of the upper housing 12, lower housing 13, and substrate 11 slightly differ from those of the optical module 60 in accordance with the second embodiment. The other structures are substantially the same as those of the optical module 60 in accordance with the second embodiment.

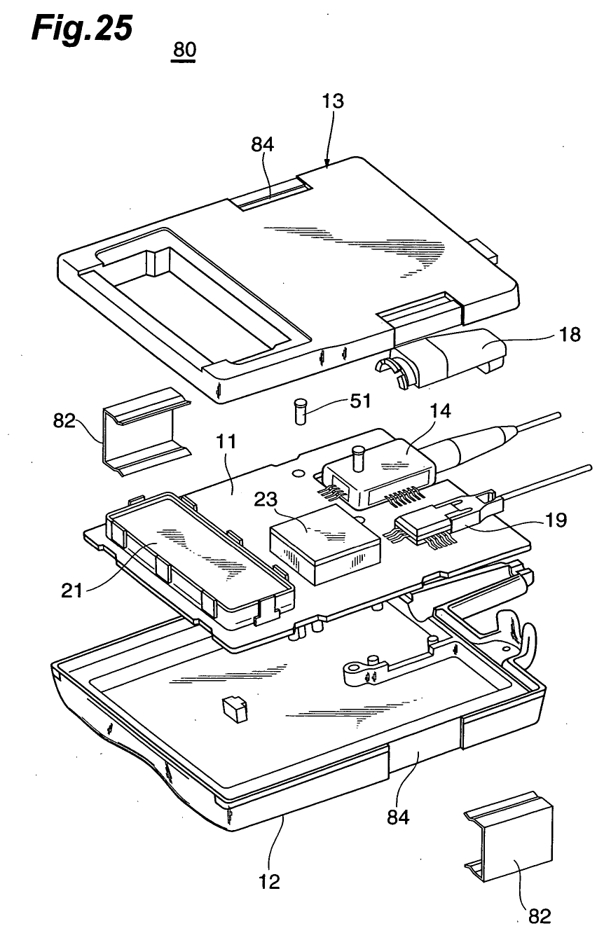

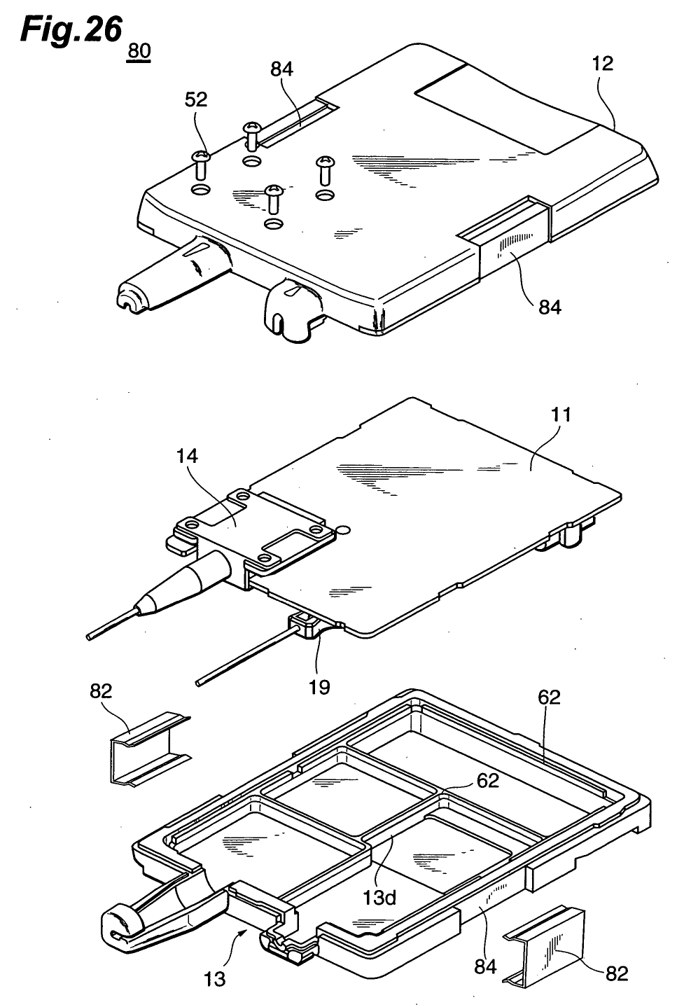

FIG. 25 is an exploded perspective view of the optical module 80 in accordance with the third embodiment as looked up from the lower housing 13 side. FIG. 26 is an exploded perspective view of the optical module 80 in accordance with the third embodiment as looked down from the upper housing 12 side.

When FIGS. 15 and 16 are compared with FIGS. 25 and 26, respectively, the optical module 80 in accordance with the third embodiment is free of the screw holes (13f in FIGS. 15 and 16) for screwing in the lower housing 13 and the escapes for heads of screws (53 in FIG. 15). Correspondingly, the upper housing 12 is free of screw holes (12f in FIG. 15). Further, the substrate 11 of the optical module 80 is free of the cutouts (11d in FIGS. 15 and 16) for letting the screws 53 out, which are formed in the substrate 11 of the optical module 60 in accordance with the second embodiment. Therefore, the area of the front and rear faces of the substrate 11 (i.e., the mounting area on which components can be mounted) is greater than that in the substrate 11 of the optical module 60 in accordance with the second embodiment.

Main advantages of this embodiment will now be explained. This embodiment yields the following advantages in addition to the eight advantages of the above-mentioned second embodiment.

Since the upper and lower housings 12, 13 are connected to each other by being held by the clips 82 instead of screwing, the mounting area of the substrate 11 increases. Therefore, when the housing size is held constant, the mounting components and wires on the substrate 11 can be increased, whereby higher functions can be achieved. When the circuit configuration is the same, the outer form of the substrate 11 can be made smaller, which reduces the housing size, thereby decreasing the size of the optical module itself. Also, it is unnecessary for the housings to be processed for screwing, and the assembling man hour is smaller than that in the case with screwing, whereby the assembling workability is higher.

The present invention is explained in detail based on its embodiments in the foregoing. However, the present invention is not limited to the above-mentioned embodiments. The present invention can be modified in various manners within the scope not deviating from the gist thereof.

The above-mentioned first to third embodiments relate to optical modules equipped with both of the LD module 14 and pin AMP 19 as the optical modules 10, 60, 80. Without being restricted thereto, the present invention is applicable in optical transmitter modules equipped with the LD module 14 alone and optical receiver modules equipped with the Pin AMP 19 alone.

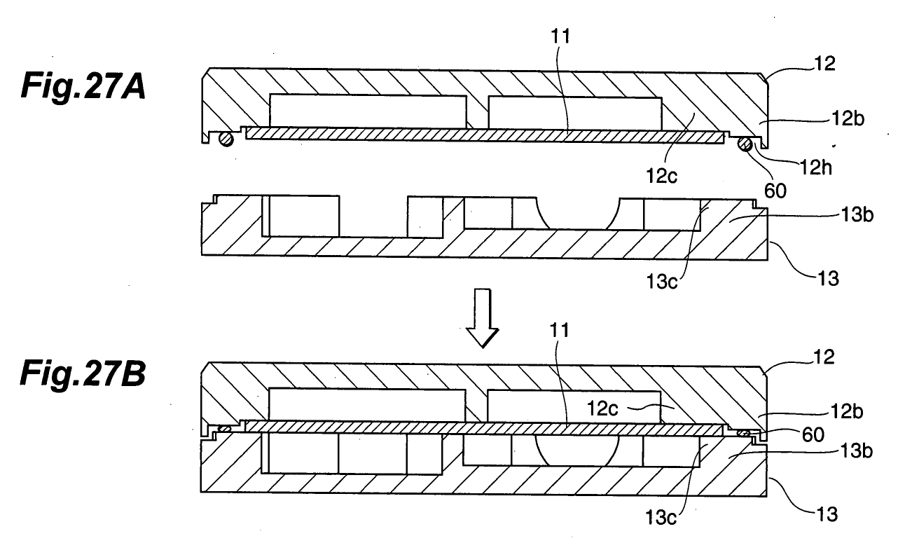

The optical module of the above-mentioned first embodiment can be modified as follows. FIGS. 27A and 27B are views showing an assembling operation when a gasket is used in the optical module 10 of the first embodiment. As shown in FIG. 27A, the gasket 60 is disposed at a ring-like depression 12h formed in the upper face of the side wall part 12b of the upper housing 12. The depression 12h is disposed on the outside of the upper support part 12c. The bottom face of the depression 12h is higher than the upper face of the upper support part 12c. Namely, the side wall part 12b is formed with two stepped parts, so that the substrate 11 and the gasket 60 are disposed at the inner and outer stepped parts, respectively.

The upper housing 12 having the substrate 11 and gasket 60 attached thereto covers the lower housing 13 and is fastened with the screws 53. As shown in FIG. 27B, the substrate 11 and gasket 60 are held between the upper housing 12 and lower housing 13. However, the upper housing 12 and lower housing 13 do not directly come into contact with each other. The gasket 60 is collapsed by these housings. The amount of distortion of the gasket is preferably within a recommended range thereof. FIGS. 27A and 27B omit the screws 53, screw holes 12f, and through holes 13f.

Though the elastic member 62 is disposed between the lower housing 13 and substrate 11 in the optical module 60 of the above-mentioned second embodiment, an elastic member may be disposed between the upper housing 12 and substrate 11, or respective elastic members may be disposed between the upper housing 12 and substrate 11 and between the lower housing 13 and substrate 11.

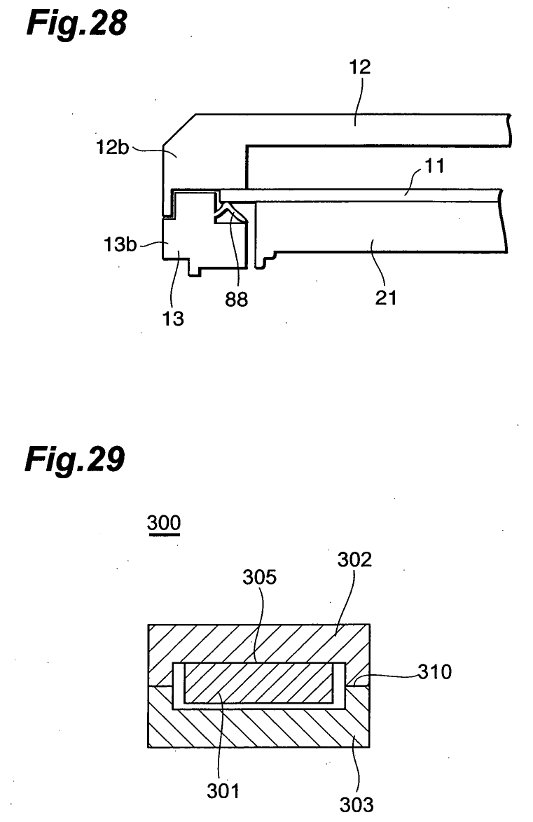

As shown in FIG. 28, the elastic member may be constituted by a leaf spring piece 88 which is provided in at least one of the upper housing 12 and lower housing 13. FIG. 28 shows a state where the lower housing 13 is provided with the leaf spring piece 88 acting as the elastic member.

The substrate 11 is disposed within the stepped part formed in the side wall part 12b of the upper housing 12 in the optical module 10 in accordance with the first embodiment, and within the stepped part formed in the side wall part 13b of the lower housing 13 in the optical modules 60, 80 in accordance with the second and third embodiments. Without being restricted thereto, both of the side wall parts 12b, 13b of the upper housing 12 and lower housing 13 may be formed with stepped parts, and the substrate 11 may be disposed within these stepped parts.

The upper housing 12 and lower housing 13 may also be held by the clips 82 so as to be connected to each other without being screwed in the optical module 10 in accordance with the first embodiment.

From the foregoing explanations of the invention, it will be obvious that the same may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

The optical module in accordance with the present invention can improve the mounting area of the substrate. This achieves a higher function or smaller size in the optical module.

1. An optical module comprising:
a substrate having a front face and a rear face;
at least one of a light-emitting module and a light-receiving module, mounted on the substrate; and
a housing for receiving the substrate;
wherein the housing comprises an upper housing and a lower housing, the upper housing being disposed on the rear face side of the substrate and in contact with the rear face, the lower housing being disposed on the front face side of the substrate and in contact with the front face; and
wherein the substrate is held between the upper and lower housings.

2. An optical module according to claim 1, wherein the upper and lower housings each include a bottom wall part extending along the substrate, and a side wall part provided at a peripheral portion of the bottom wall part; and
wherein a peripheral part of the substrate is held between the side wall part of the upper housing and the side wall part of the lower housing.

3. An optical module according to claim 2, wherein at least one of upper faces of the side wall parts of the upper and lower housings is provided with a stepped part; and
wherein the substrate is disposed within the stepped part.

4. An optical module according to claim 2, wherein a partition wall is provided on the bottom wall part of the lower housing so as to form a plurality of rooms; and
wherein a plurality of components are separately set in the plurality of rooms.

5. An optical module according to claim 2, wherein an electrical connector is mounted on the front face of the substrate;
wherein a boss is provided on the bottom wall part of the upper housing; and
wherein the boss abuts against the rear face of the substrate at a position where the electrical connector is mounted.

6. An optical module according to claim 1, wherein the upper and lower housings are kept from being directly in contact with each other; and wherein a gasket is disposed in a gap between the upper and lower housings.

7. An optical module according to claim 1, wherein the substrate is held between the upper and lower housings by way of an elastic member.

8. An optical module according to claim 7, wherein an electrical connector is mounted on the front face of the substrate; and
wherein the elastic member is disposed between the lower housing and the front face of the substrate.

9. An optical module according to claim 7, wherein the elastic member is constituted by a silicone-based conductive material.

10. An optical module according to claim 7, wherein the elastic member is constituted by a metal material.

11. An optical module according to claim 7, wherein the elastic member is constituted by a leaf spring piece provided in at least one of the upper and lower housings.

12. An optical module according to claim 4, wherein an elastic member is disposed between an upper face of the partition wall and the front face of the substrate.

13. An optical module according to claim 1, wherein the upper and lower housings are connected to each other by screwing.

14. An optical module according to claim 1, wherein the upper and lower housings are connected to each other by being held by a clip.

15. An optical module according to claim 14, wherein a part of the upper and lower housings held by the clip is provided with a depression fitting over the clip.
